(19) United States
(12) Patent Application Publication
(10) Pub. No.: US 2016/0172418 A1
(43) Pub. Date: Jun. 16, 2016

(54) METHOD OF MANUFACTURING CMOS IMAGE SENSOR

(71) Applicant: Samsung Electronics Co., Ltd., Suwon-si (KR)

(72) Inventors: Sang Hoon KIM, Seongnam-si (KR); Sang il Jung, Seoul (KR)

(21) Appl. No.: 14/956,879

(22) Filed: Dec. 2, 2015

(30) Foreign Application Priority Data
Dec. 11, 2014 (KR) 10-2014-0178714

(51) Int. Cl. H01L 27/146

(52) U.S. Cl. CPC H01L 27/14689

(57) ABSTRACT

Methods of manufacturing a complementary metal oxide semiconductor (CMOS) image sensor, include forming, in a semiconductor substrate, at least one device isolation layer defining an active area; forming at least one gate dielectric layer on the active area; forming at least one gate on the active area and the at least one device isolation layer, wherein first conductive-type impurity ions are injected into the at least one gate; and injecting second conductive-type impurity ions into portions of the at least one gate arranged on the at least one device isolation layer and edges of the active area adjacent to the at least one device isolation layer.

### CROSS-REFERENCE TO RELATED APPLICATION

This application claims the benefit of priority under 35 U.S.C. §119 from Korean Patent Application No. 10-2014-0178714, filed on Dec. 11, 2014, in the Korean Intellectual Property Office, the disclosure of which is incorporated herein in its entirety by reference.

### BACKGROUND

1. Field

Example embodiments of the inventive concepts relate to methods of manufacturing a complementary metal oxide semiconductor (CMOS) image sensor, and more particularly, to methods of manufacturing a CMOS image sensor including a source follower transistor that generates a small amount of flicker noise and random telegraph signal (RTS) noise due to double doping of a gate.

2. Related Art

CMOS image sensors may be easily manufactured with low manufacturing costs in comparison with charge coupled devices (CCD), and thus, the CMOS image sensor is widely used in solid-state imaging applications. Also, a unit pixel of the CMOS image sensor is implemented in a smaller area than a unit pixel of the CCD because the unit pixel includes MOS transistors. As a result, the CMOS image sensor may have a high resolution. In addition, because a signal processing logic may be implemented in an image circuit in which pixels are formed, the image circuit and a signal processing circuit may be integrated into a single circuit. However, a source follower transistor of the CMOS image sensor generates a large amount of flicker noise and RTS noise, and thus, the sensitivity of the CMOS image sensor may be low.

### SUMMARY

Example embodiments of the inventive concepts relate to methods of manufacturing a complementary metal oxide semiconductor (CMOS) image sensor, and more particularly, to methods of manufacturing a CMOS image sensor including a source follower transistor that generates a small amount of flicker noise and random telegraph signal (RTS) noise due to double doping of a gate.

Example embodiments of the inventive concepts provide a method of manufacturing a complementary metal oxide semiconductor (CMOS) image sensor including a source follower transistor that generates a small amount of flicker noise and random telegraph signal (RTS) noise.

According to example embodiments of the inventive concepts, there is provided a method of manufacturing a complementary metal oxide semiconductor (CMOS) image sensor, the method including forming, in a semiconductor substrate, at least one device isolation layer defining an active area; forming at least one gate dielectric layer on the active area; forming at least one gate on the active area and the at least one device isolation layer, wherein a plurality of first conductive-type impurity ions are injected into the at least one gate; and injecting a plurality of second conductive-type impurity ions into portions of the at least one gate arranged on the at least one device isolation layer and edges of the active area adjacent to the at least one device isolation layer.

The forming of the at least one gate may include forming a material layer on the at least one device isolation layer and the at least one gate dielectric layer; injecting the first conductive-type impurity ions into the material layer; and forming at least one gate by patterning the material layer.

The forming the material layer may include using polysilicon.

The injecting of the plurality of second conductive-type impurity ions may include forming a first photo mask pattern exposing the portions of the at least one gate and the edges of the active area; injecting the second conductive-type impurity ions into the exposed portions of the at least one gate; and removing the first photo mask pattern.

The injecting of the plurality of second conductive-type impurity ions may include adjusting a threshold voltage of the edges of the active area to be greater than a threshold voltage of a central portion of the active area.

The injecting of the plurality of second conductive-type impurity ions may include generating, by a voltage applied to the at least one gate, a greater amount of a current through a central portion of the active area than through the edges of the active area.

An injection amount of the first conductive-type impurity ions may be less than an injection amount of the second conductive-type impurity ions.

The forming of the at least one gate may include forming a gate of a source-follower transistor, and the source-follower transistor may be configured to amplify a potential change of a floating diffusion area.

According to example embodiments of the inventive concepts, there is provided a method of manufacturing a CMOS image sensor, the method include forming, in a semiconductor substrate, at least one device isolation layer defining an active area; injecting a first plurality of first conductive-type impurity ions into a central portion of the active area; forming a gate dielectric layer on the active area; forming a material layer on the device isolation layers and the gate dielectric layer; injecting a second plurality of the first conductive-type impurity ions into the material layer; and forming a gate by patterning the material layer.

The injecting of the first plurality of first conductive-type impurity ions may include injecting N-type impurity ions.

An injection amount of the first plurality of the first conductive-type impurity ions may be less than an injection amount of the second plurality of the first conductive-type impurity ions.

The forming of the gate may include forming the gate between a reset gate and a select gate. The reset gate and select gate may be formed in a selected area of the active area and may be separated from each other by a set distance.

A voltage applied to the gate may generate a greater amount of a current through the central portion of the active area than through edges of the active area adjacent to the device isolation layers.

The method may further include, after the forming of the gate, injecting a plurality of second conductive-type impurity ions into a portion of the gate on the at least one device isolation layer and edges of the active area adjacent to the at least one device isolation layer.

The injecting of the plurality of second conductive-type impurity ions may include injecting P-type impurity ions.

According to example embodiments, a method of manufacturing a complementary metal oxide semiconductor (CMOS) image sensor, includes providing a semiconductor substrate including at least one device isolation layer defining an active area of the semiconductor substrate, forming a material layer on the active area and the at least one device isolation layer, forming a gate structure including a first impurity region and a second impurity region by performing a double doping process, the double doping process including injecting a first plurality of conductive-type impurity ions and subsequently injecting a second plurality of conductive-type impurity ions into the material layer, and patterning the gate structure to form a gate. A dopant concentration of the first impurity region is different than a dopant concentration of the second impurity region.

The performing the double doping process may include injecting the first plurality of conductive-type impurity ions in a central portion of the active area.

The injecting the first plurality of conductive-type impurity ions and the injecting the second plurality of conductive-type impurity ions may include injecting N-type impurity ions. An amount of the first plurality of conductive-type impurity ions may be less than an amount of the second plurality of conductive-type impurity ions.

The performing the double doping process may include injecting the first plurality of conductive-type impurity ions in a central portion of the material layer, and injecting the second plurality of the conductive-type impurity ions into edges of the material layer.

The method may further include forming a photo mask pattern exposing the edges of the material layer simultaneously with the injecting the second plurality of the conductive-type impurity ions, wherein the forming the photo mask pattern and the injecting the second plurality of conductive-type impurity ions include injecting P-type impurity ions.

### BRIEF DESCRIPTION OF THE DRAWINGS

Example embodiments of the inventive concepts will be more clearly understood from the following detailed description taken in conjunction with the accompanying drawings in which:

FIG. 1 is a circuit diagram of a unit pixel of a complementary metal oxide semiconductor (CMOS) image sensor according to example embodiments of the inventive concepts;

FIG. 2 is a plan view of a unit pixel of a CMOS image sensor according to example embodiments of the inventive concepts;

FIG. 3 is a cross-sectional view of a CMOS image sensor, taken along a line B-B′ of FIG. 2;

FIGS. 4 to 10 are cross-sectional views taken along a line A-A′ of FIG. 2 in order to explain a method of manufacturing a CMOS image sensor, according to example embodiments of the inventive concepts;

FIGS. 11 to 15 are cross-sectional views taken along a line A-A′ of FIG. 2 in order to explain a method of manufacturing a CMOS image sensor, according to example embodiments of the inventive concepts;

FIGS. 16 and 17 are cross-sectional views taken along a line A-A′ of FIG. 2 in order to explain a method of manufacturing a CMOS image sensor, according to example embodiments of the inventive concepts; and

FIG. 18 is a block diagram of an imaging system including a CMOS image sensor manufactured by a method of manufacturing a CMOS image sensor, according to example embodiments of the inventive concepts.

### DETAILED DESCRIPTION OF EXAMPLE EMBODIMENTS

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various features will be described in detail with reference to the attached drawings. However, example embodiments described are not limited thereto.

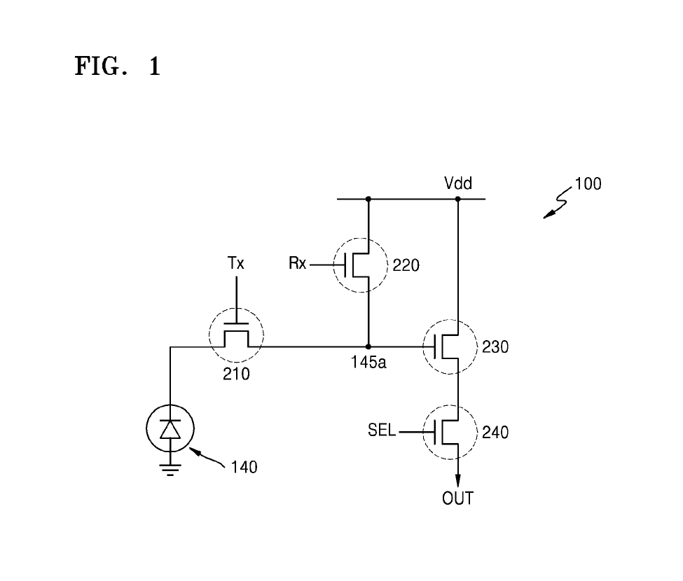

Example embodiments of the inventive concepts relate to methods of manufacturing a complementary metal oxide semiconductor (CMOS) image sensor, and more particularly, to methods of manufacturing a CMOS image sensor including a source follower transistor that generates a small amount of flicker noise and random telegraph signal (RTS) noise due to double doping of a gate. Hereinafter, one or more example embodiments of the inventive concepts will be described in detail with reference to FIGS. 1 to 18.

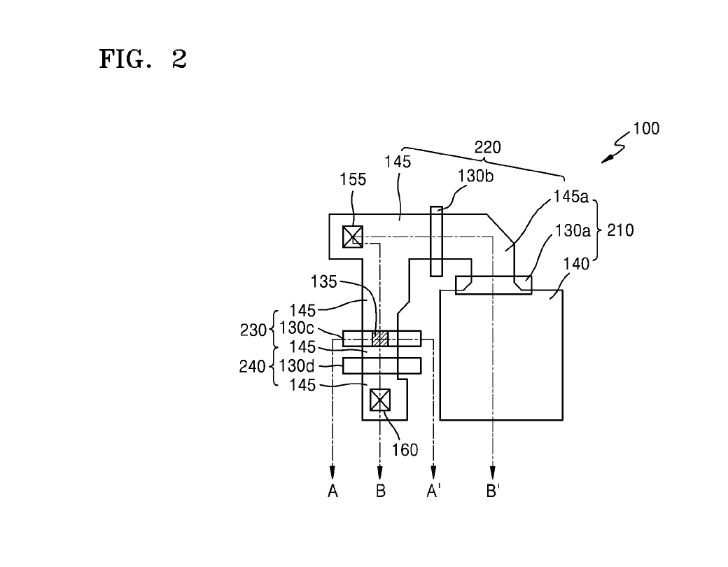

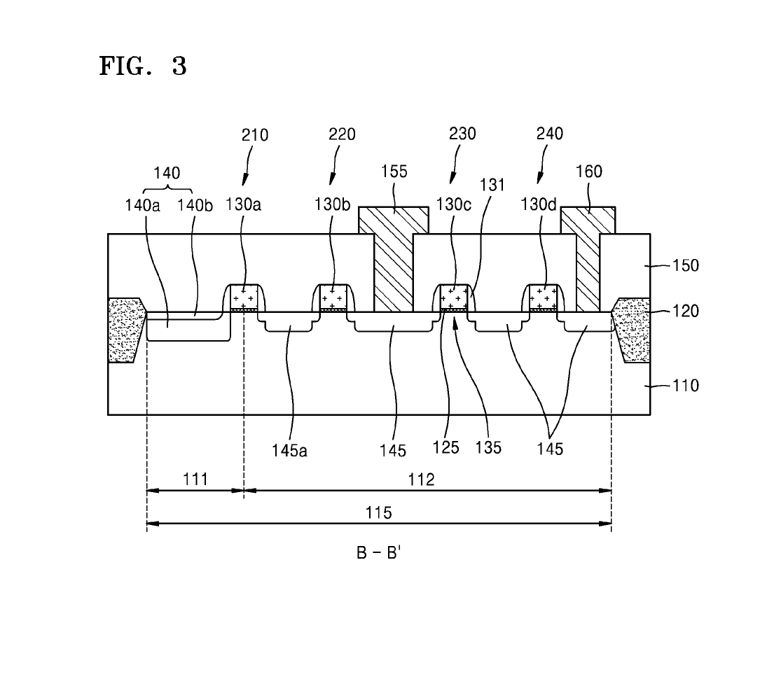

FIG. 1 is a circuit diagram of a unit pixel of a complementary metal oxide semiconductor (CMOS) image sensor according to example embodiments of the inventive concepts, FIG. 2 is a plan view of the unit pixel of the CMOS image sensor according to example embodiments of the inventive concepts, and FIG. 3 is a cross-sectional view of the CMOS image sensor, taken along a line B-B′ of FIG. 2.

Referring to FIG. 1, an unit pixel 100 of a CMOS image sensor includes a photo diode 140, a transfer transistor 210 configured to transmit electric charges captured by the photo diode 140, a floating diffusion area 145a in which the electric charges transmitted by the transfer transistor 210 are stored, a reset transistor 220 configured to periodically reset the floating diffusion area 145a, a source follower transistor 230 configured to amplify the electric charges stored in the floating diffusion area 145a, and a select transistor 240 configured to output output signals of the source follower transistor 230 according to unit pixel select signals SEL. Tx indicates transfer transistor signals, and Rx indicates reset transistor signals.

Referring to FIGS. 2 and 3, the photo diode 140, the floating diffusion area 145a, the transfer transistor 210, the reset transistor 220, the source follower transistor 230, and the select transistor 240 which are included in the unit pixel 100 of the CMOS image sensor are integrated into an active area 115 formed in a semiconductor substrate 110. The active area 115 is defined by forming device isolation layers 120 in the semiconductor substrate 110. The active area 115 may be divided into a first active area 111, where the photo diode 140 is to be formed, and a second active area 112 where the transfer, reset, source follower, and select transistors 210, 220, 230, and 240 are to be formed, the second active area 112 extending from a set (or, predetermined) portion of the first active area 111. To increase a fill factor, it is advantageous that the first active area 111 occupies most area of the unit pixel 100 of the CMOS image sensor. For example, the first active area 111 may have a rectangular plate form. The second active area 112 extends from a set (or, predetermined) portion of the first active area 111 and may include a line pattern having a set (or, predetermined) width. The second active area 112 may be curved such that the second active area 112 may be effectively arranged in a narrow space in the unit pixel 110 of the CMOS image sensor.

Transfer, reset, source follower, and select gates 130a, 130b, 130c, and 130d of the transfer, reset, source follower, and select transistors 210, 220, 230, and 240 are arranged in select (or, predetermined) portions of the active area 115 in order to respectively form the transfer, reset, source follower, and select transistors 210, 220, 230, and 240. The transfer gate 130a may be arranged on a boundary region of the first active area 111 and the second active area 112 of the active area 115, and the reset gate 130b, the source follower gate 130c, and the select gate 130d may be arranged on the second active area 112 of the active area 115 at regular intervals. Gate dielectric layers 125 may be respectively arranged between the active area 115 and the transfer, reset, source follower, and select gates 130a, 130b, 130c, and 130d. Also, insulating spacers 131 may be formed on side walls of each of the transfer, reset, source follower, and select gates 130a, 130b, 130c, and 130d.

An N-type impurity ion doping area 140a and a P-type impurity ion doping area 140b are formed in the first active area 111 on one side of the transfer gate 130a, and thus, the photo diode 140 is formed. The P-type impurity ion doping area 140b is formed on a surface of the N-type impurity ion doping area 140a and removes dark sources.

The floating diffusion area 145a is formed on the other surface of the transfer gate 130a by using N-type impurity ions, and junction areas 145 are respectively formed on a side of the reset gate 130b, both sides of the source follower gate 130c, and both sides of the select gate 130d by using N-type impurity ions. In this case, because the transfer, reset, source follower, and select gates 130a, 130b, 130c, and 130d of the transfer, reset, source follower, and select transistors 210, 220, 230, and 240 are formed to be adjacent to each other, the transfer, reset, source follower, and select gates 130a, 130b, 130c, and 130d may share the junction areas 145. Also, the floating diffusion area 145a and the junction areas 145 may be formed by a lightly doped drain (LDD) method. After the floating diffusion area 145a and the junction areas 145 are formed, the transfer transistor 210, the reset transistor 220, the source follower transistor 230, and the select transistor 240 are formed in the active area 115.

A Vdd contact 155 that contacts the junction area 145 of the reset transistor 220, for example, the junction area 145 between the reset gate 130b and the source follower gate 130c, is formed, and a Vout contact 160 that contacts the junction area 145 on one side of the select transistor 240 is formed. The reference numeral 150 indicates an interlayer insulating layer.

As described above, the source follower transistor 230 amplifies the electric charges stored in the floating diffusion area 145a. In this case, undesired electric charges are injected due to a lattice defect, etc. which occurs at an interface between the semiconductor substrate 110 and the device isolation layers 120, and thus, flicker noise, random telegraph signal (RTS) noise, etc. may be generated in the CMOS image sensor.

According to a method of manufacturing the CMOS image sensor according to example embodiments of the inventive concepts, double doping is performed for the source follower gate 130c of the source follower transistor 230 and/or channel doping is performed for a central portion 135 of the active area 115 of the source follower transistor 230. Thus, a current flows through the central portion 135 of the active area 115 of the source follower transistor 230. As a result, the CMOS image sensor including a source follower transistor 230 that generates a small amount of flicker noise and RTS noise may be manufactured.

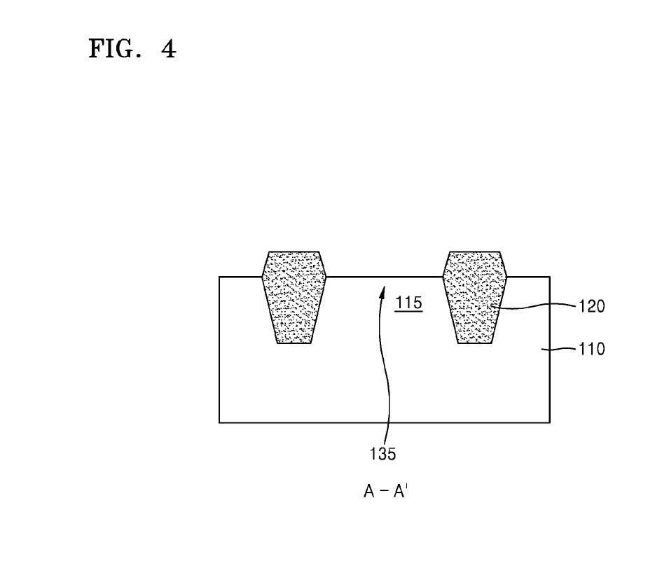

FIGS. 4 to 10 are cross-sectional views taken along a line A-A′ of FIG. 2 in order to explain a method of manufacturing a CMOS image sensor, according to example embodiments of the inventive concepts.

Referring to FIG. 4, the device isolation layers 120 are formed to form the source follower transistor (230, refer to FIGS. 1 and 2) in the semiconductor substrate 110, and the active area 115 is defined.

The semiconductor substrate 110 may include silicon (Si), for example, single-crystal silicon, poly silicon, or amorphous silicon. In example embodiments, the semiconductor substrate 110 may include germanium (Ge) or a compound semiconductor such as SiGe, silicon carbide (SiC), gallium arsenide (GaAs), indium arsenide (InAs), or indium phosphide (InP). In example embodiments, the semiconductor substrate 110 may include a conductive region, for example, a well doped with impurity ions or a structure doped with impurity ions. Hereinafter, in the present example embodiments, a case where the semiconductor substrate 110 is a Si substrate will be described.

The device isolation layers 120 may be a single insulating layer, but may include an external insulating layer and an internal insulating layer. The external insulating layer and the internal insulating layer may be formed of different materials. For example, the external insulating layer may be an oxide layer, and the internal insulating layer may be a nitride layer. However, a structure of the device isolation layers 120 is not limited thereto. For example, the device isolation layers 120 may be a multilayer including a combination of at least three types of insulating layers.

In the semiconductor substrate 110, a portion divided by the device isolation layers 120 may be the active area 115. The active area 115 may be a portion of an area where the source follower transistor (230, refer to FIGS. 1 and 2) is formed. After the source follower transistor (230, refer to FIGS. 1 and 2) is formed, a current flows through the active area 115. In this case, because the semiconductor substrate 110 and the device isolation layers 120 may be formed of different materials, a lattice defect may occur at an interface. The lattice defect generates an undesired current flow by randomly collecting electric charges or discharging the collected electric charges. Thus, flicker noise and RTS noise may be generated due to the undesired current flow, which may degrade sensitivity of the CMOS image sensor.

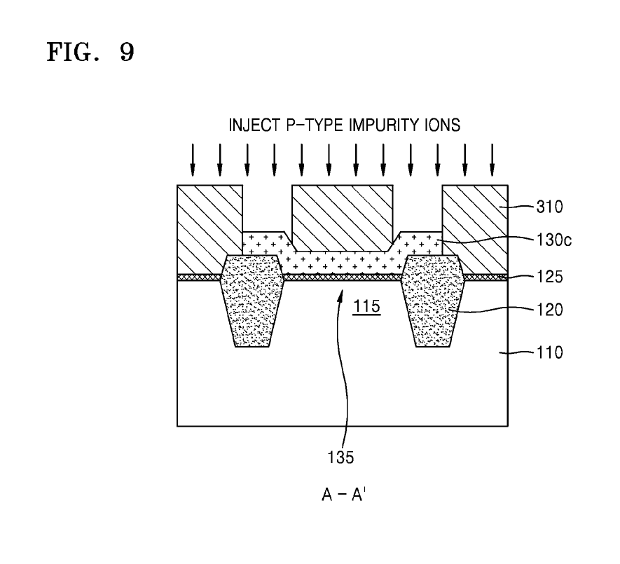

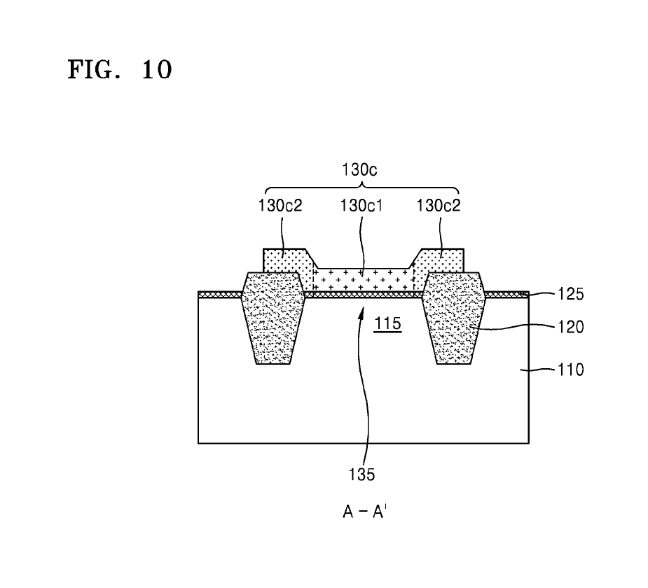

Therefore, in order to solve the above-described problem, double doping is performed for the source follower gate (130c, refer to FIG. 10) such that a current flows in the central portion 135 of the active area 115 instead of an area where the active area 115 is adjacent to the device isolation layers 120. Detailed descriptions regarding the double doping will be provided again with reference to FIG. 9.

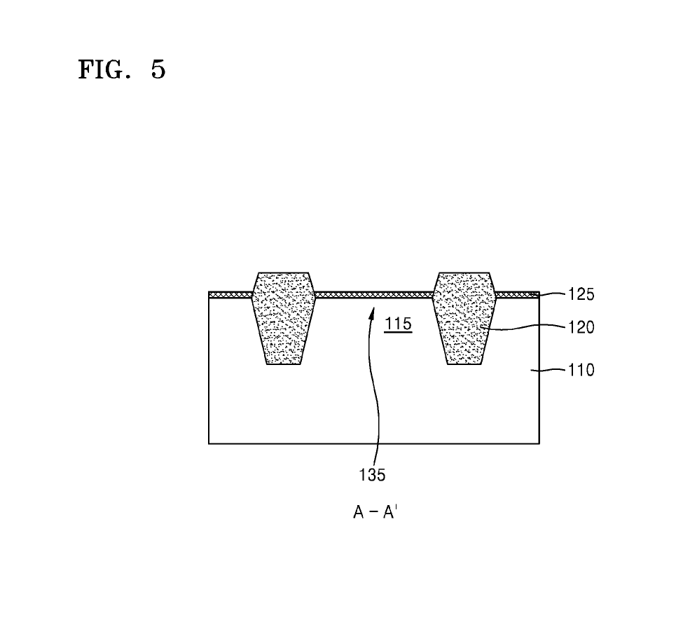

Referring to FIG. 5, the gate dielectric layer 125 is formed on the semiconductor substrate 110.

The gate dielectric layer 125 may be formed of at least one material selected from a silicon oxide layer, a silicon nitride layer, a silicon oxynitride layer, an oxide/nitride/oxide (ONO) layer, or a high-k dielectric film having a greater dielectric constant than a silicon oxide layer. For example, the gate dielectric layer 125 may have dielectric constants ranging from about 10 to about 25. In some example embodiments, the gate dielectric layer 125 may be formed of at least one material selected from the group consisting of hafnium oxide (HfO), hafnium silicon oxide (HfSiO), hafnium oxynitride (HfON), hafnium silicon nitride (HfSiON), lanthanum silicon oxide (LaO), lanthanum aluminum oxide (LaAlO), zirconium oxide (ZrO), zirconium silicon oxide (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), AlO, and lead scandium tantalum (PbScTaO).

Hereinafter, in the present example embodiments, a case where the gate dielectric layer 125 is a silicon oxide layer will be described. The silicon oxide layer may be formed by a medium temperature oxide (MTO) process.

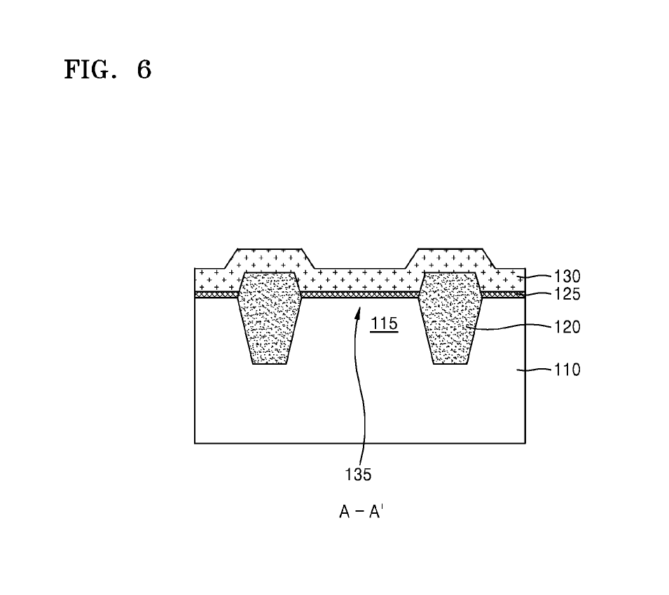

Referring to FIG. 6, a material layer 130 for forming a gate is formed on the gate dielectric layer 125 and the device isolation layers 120.

The material layer 130 may be a single layer or multiple layers. The material layer 130 may include a semiconductor material such as polysilicon which is not doped or lightly doped or other materials.

Hereinafter, in the present example embodiments, a case where the material layer 130 includes polysilicon will be described.

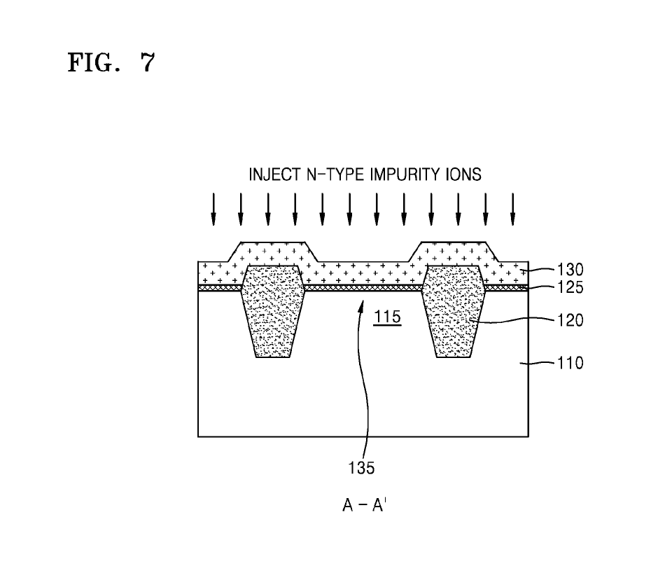

Referring to FIG. 7, first conductive-type impurity ions are injected into the material layer 130.

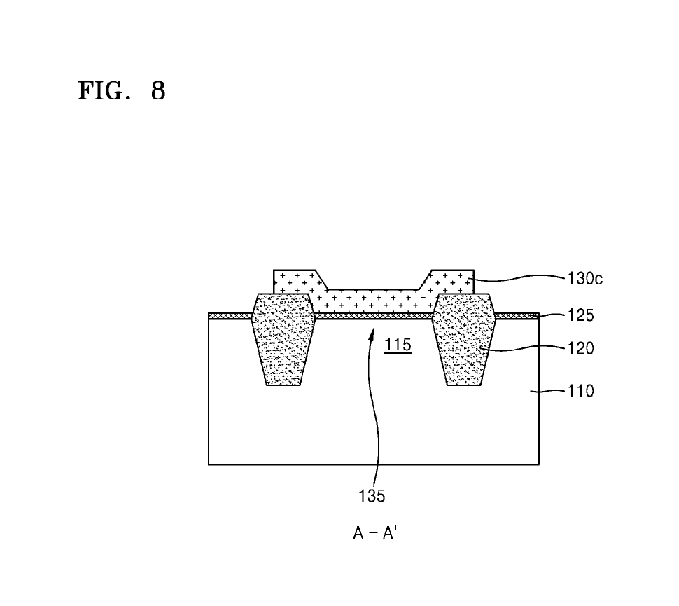

The first conductive-type impurity ions may be N-type impurity ions. The material layer 130 may include polysilicon that is not doped or lightly doped. Also, because it is required that the source follower gate 130c (refer to FIG. 8) is formed of a conductive material, the source follower gate 130c is doped with polysilicon to have conductivity. For example, the source follower gate 130c (refer to FIG. 8) may be formed of polysilicon that is doped and may have conductivity by injecting the N-type impurity ions and performing a thermal treatment process.

An entire portion of the material layer 130 may be doped with the N-type impurity ions through a process of injecting the N-type impurity ions. Also, the entire portion of the material layer 130 may be doped with P-type impurity ions through a process of injecting the P-type impurity ions.

Referring to FIG. 8, the source follower gate 130c is formed by performing photolithography and an etching process for the material layer (refer to FIG. 7).

The source follower gate 130c may be formed on the active area 115 between the device isolation layers 120 and on portions of the device isolation layers 120 in order to prevent the generation of a leakage current. That is, the source follower gate 130c may be formed on the central portion 135 of the active area 115, edges thereof that are adjacent to the device isolation layers 120, and the portions of the device isolation layers 120.

Referring to FIGS. 9 and 10, a first photo mask pattern 310 is formed to exposes edges of the source follower gate 130c, and then second conductive-type impurity ions are injected into the first photo mask pattern 310 and exposed edges of the source follower gate 130c.

The second conductive-type impurity ions may be P-type impurity ions.

The source follower gate 130c is double-doped through the process of injecting the P-type impurity ions. The source follower gate 130c may have a central portion 130c1 and edges 130c2. The central portion 130c1 of the source follower gate 130c indicates a portion of the source follower gate 130c on the central portion 135 of the active area 115. That is, the central portion 130c1 of the source follower gate 130c includes polysilicon doped with N-type impurity ions, and the edges 130c2 of the source follower gate 130c include polysilicon doped with P-type impurity ions. Because the entire portion of the source follower gate 130c is doped with the N-type impurity ions through the process of injecting the N-type impurity ions, an injection amount of the P-type impurity ions needs to be greater than that of the N-type impurity ions. A doping process in which ions of an opposite type with respect to previously injected ions are injected is referred to as counter doping. Through the counter doping, the source follower gate 130c may include polysilicon doped in a P (an edge portion)-N (a central portion)-P (an edge portion) type.

The source follower gate 130c is formed because a lattice defect may occur at an interface between the semiconductor substrate 110 and the device isolation layers 120, wherein the semiconductor substrate 110 and the device isolation layers 120 may be formed of different materials. The lattice defect may include, for example, dangling bonds. Due to the lattice defect such as the dangling bonds, electric charges of a current flowing in the active area 115 may be randomly collected in the lattice defect. Therefore, the lattice defect affects a current flow, and due to an undesired current flow, flicker noise and RTS noise may be generated in the CMOS sensor. The generation of the flicker noise and RTS noise may degrade the sensitivity of the CMOS image sensor.

Therefore, it is necessary to make a current which flows in the active area 115 of the source follower transistor (230, refer to FIGS. 1 and 2) flow toward the central portion 135 of the active area 115 instead of the edges of the active area 115 adjacent to the device isolation layers 120. Through the counter doping, the current may flow toward the central portion 135 of the active area 115 by forming a threshold voltage of the active area 115 adjacent to the device isolation layers 120 to be relatively greater than that of the central portion 135 of the active area 115.

A source follower transistor (230, refer to FIGS. 1 and 2) having a small amount of flicker noise and RTS noise may be manufactured by making the current flow toward the central portion 135 of the active area 115 having a small concentration gradient after the concentration gradient is implemented in the active area 115 and then by decreasing an amount of electric charges collected in the interface between the semiconductor substrate 110 and the device isolation layers 120.

The process of injecting the P-type impurity ions may be simultaneously performed with the process of injecting the P-type impurity ions during the process of forming the photo diode (140, refer to FIGS. 1 and 2) and the signal processing logic. That is, the P-type impurity ions may be injected without performing additional processes by using processes that are performed according to the general method of manufacturing the CMOS image sensor. Therefore, according to one or more example embodiments of the inventive concepts, an effect that is the same as an effect of performing the double doping for the source follower gate 130c may be achieved without increasing the manufacturing costs.

After the process of injecting the P-type impurity ions is performed, the first photo mask pattern 310 is removed by ashing and strip processes, and then, the source follower gate 130c may be used as an electrode by performing a thermal treatment process.

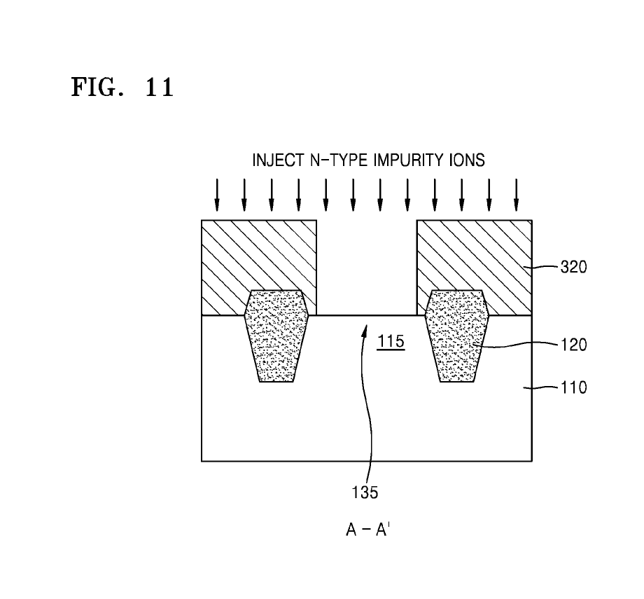

FIGS. 11 to 15 are cross-sectional views taken along a line A-A′ of FIG. 2 in order to explain a method of manufacturing a CMOS image sensor, according to example embodiments of the inventive concepts.

Referring to FIG. 11, a second photo mask pattern 320 is formed to expose the central portion 135 of the active area 115, and the first conductive-type impurity ions are injected into the second photo mask pattern 320 and the exposed central portion 135.

The first conductive-type impurity ions may be N-type impurity ions.

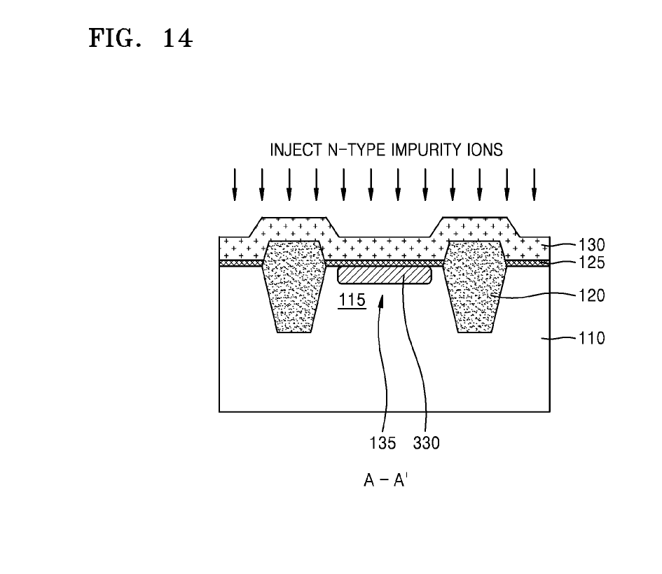

According to a general method of manufacturing a CMOS image sensor, channel doping may not be performed for the active area 115 of the source follower transistor (230, refer to FIGS. 1 and 2). However, according to one or more example embodiments of the inventive concepts, channel doping is performed for the central portion 135 of the active area 115 to induce a current flow toward the central portion 135, and thus, an amount of a current flowing toward the edges of the active area 115 adjacent to the device isolation layers 120 may be decreased. An amount of the N-type impurity ions injected during the channel doping may be less than an amount of the N-type impurity ions injected into the material layer 130 (refer to FIG. 14).

After performing the process of injecting the N-type impurity ions, the second photo mask pattern 320 may be removed by ashing and strip processes.

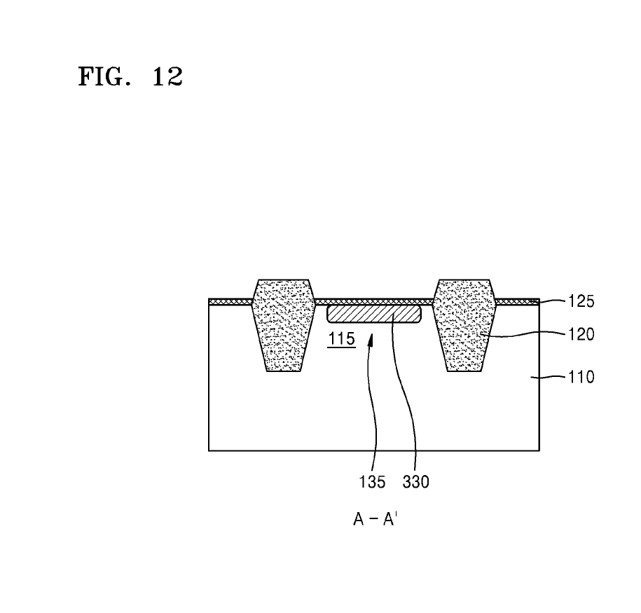

Referring to FIG. 12, a channel doping area 330 is formed in the central portion 135 of the active area 115, and then, the gate dielectric layer 125 is formed on the channel doping area 330.

The channel doping area 330 may be formed by performing the process of injecting the N-type impurity ions into the central portion 135 of the active area 115.

Descriptions regarding the remaining parts are the same as the descriptions provided with reference to FIG. 5 and thus will be omitted.

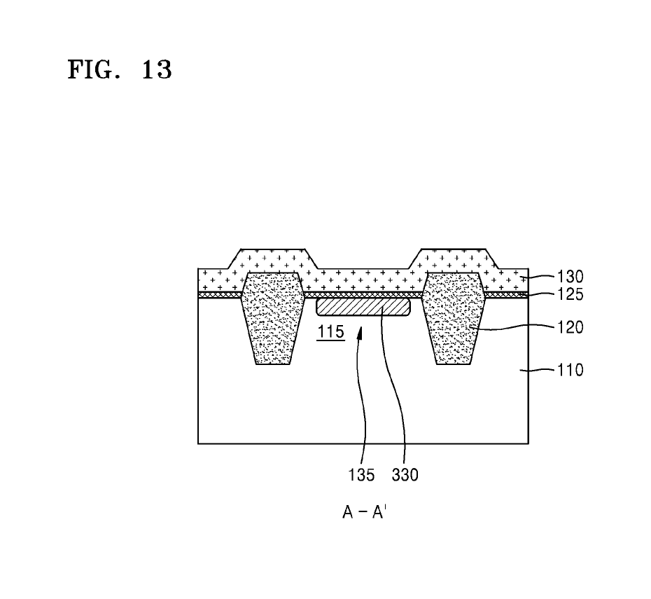

Referring to FIG. 13, the material layer 130 is formed on the gate dielectric layer 125 and the device isolation layers 120.

Descriptions regarding the formation of the material layer 130 are the same as the descriptions provided with reference to FIG. 6 and thus will be omitted.

Referring to FIG. 14 the N-type impurity ions are injected into the material layer 130.

The first conductive-type impurity ions may be N-type impurity ions.

The material layer 130 may include polysilicon that is not doped or lightly doped, and because the source follower gate 130c is an electrode, the source follower gate 130c may be doped with polysilicon to have conductivity. An amount of the N-type impurity ions injected into the channel doping area 330 may be less than an amount of the N-type impurity ions injected into the material layer 130.

Descriptions regarding the remaining parts are the same as the descriptions provided with reference to FIG. 7 and thus will be omitted.

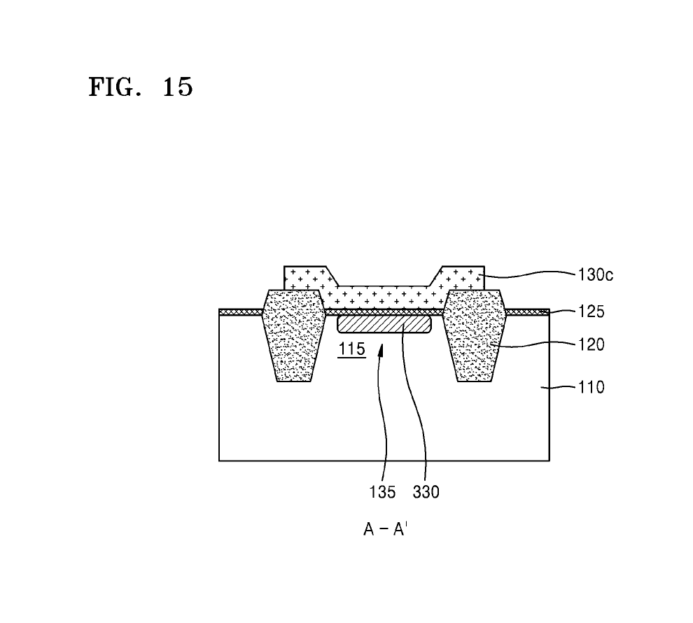

Referring to FIG. 15, the source follower gate 130c is formed by performing photolithography and an etching process for the material layer 130 (refer to FIG. 14).

Because the semiconductor substrate 110 and the device isolation layers 120 may be formed of different materials, a lattice defect may occur at an interface between the semiconductor substrate 110 and the device isolation layers 120, and thus, the channel doping area 330 is formed in the central portion 135 of the active area 115. The lattice defect may include, for example, dangling bonds. Due to the lattice defect such as the dangling bonds, electric charges of a current flowing in the active area 115 may be randomly collected in the lattice defect. Therefore, the lattice defect affects a current flow, and due to an undesired current flow, flicker noise and RTS noise may be generated in the CMOS image sensor. The generation of the flicker noise and RTS noise may degrade the sensitivity of the CMOS image sensor. The formation of the channel doping area 330 is performed in the same way as the double doping for the source follower gate 130c (refer to FIG. 10).

The channel doping is performed for the central portion 135 of the active area 115 to induce the current flow toward the central portion 135, and thus, an amount of the current flowing toward the edges of the active area 115 adjacent to the device isolation layers 120 may be decreased.

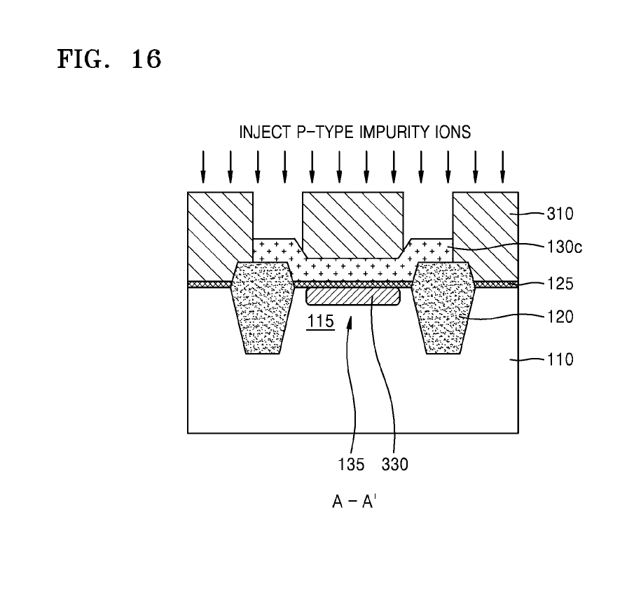

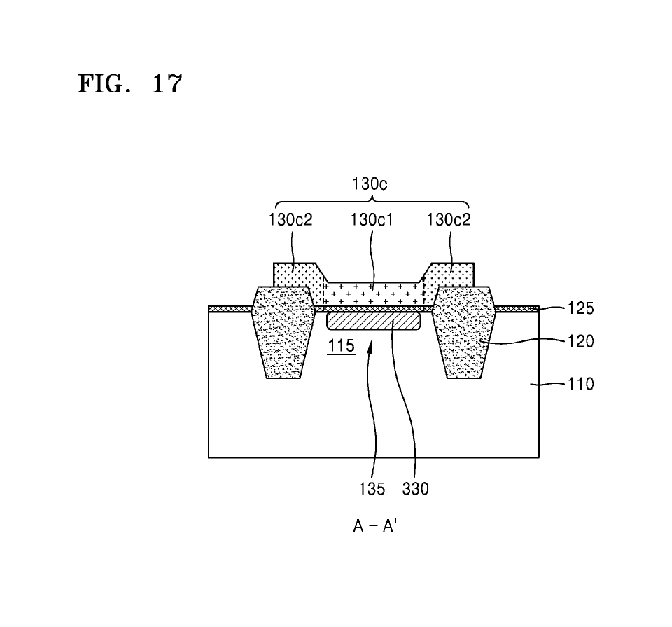

FIGS. 16 and 17 are cross-sectional views taken along a line A-A′ of FIG. 2 in order to explain a method of manufacturing the CMOS image sensor, according to example embodiments of the inventive concepts.

Referring to FIGS. 16 and 17, the first photo mask pattern 310 is formed to expose the edges 130c2 of the source follower gate 130c, and the second conductive-type impurity ions are injected into the first photo mask pattern 310 and the exposed edges 130c2 of the source follower gate 130c.

The second conductive-type impurity ions may be P-type impurity ions.

An amount of a current flowing toward the central portion 135 of the active area 115 may be increased by forming the channel doping area 330 in the central portion 135 of the active area 115 and performing double doping for the source follower gate 130c. Therefore, a source follower transistor (230, refer to FIGS. 1 and 2) that generates a small amount of flicker noise and RTS noise may be formed in the CMOS image sensor.

Descriptions regarding the remaining parts are the same as the descriptions provided with reference to FIGS. 9, 10 and 15 and thus will be omitted.

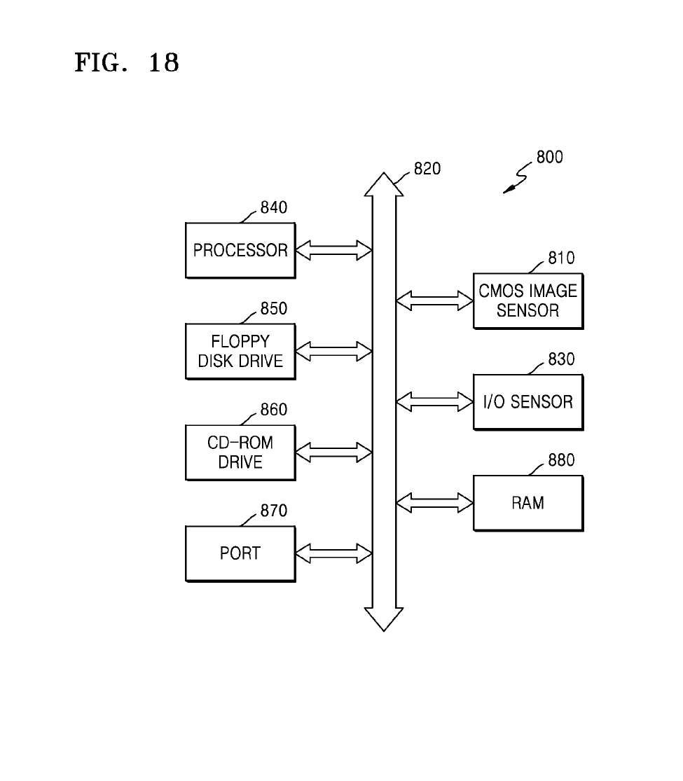

FIG. 18 is a block diagram of an imaging system including a CMOS image sensor manufactured by a method of manufacturing a CMOS image sensor, according to example embodiments of the inventive concepts.

Referring to FIG. 18, an imaging system 800 is configured to process an output image of the CMOS image sensor 810.

The imaging system 800 includes a processor 840 capable of receiving/transmitting data from/to an input/output (I/O) device 830 via a bus 820. In example embodiments, the processor 840 may be a microprocessor or a central processing unit (CPU). Regarding the imaging system 800, the processor 840 may receive/transmit data from/to a floppy disk drive 850, a CD-ROM drive 860, a port 870, and random access memory (RAM) 880 via the bus 820 and thus may reproduce output images corresponding to data of the CMOS image sensor 810.

The port 870 may be coupled to a video card, a sound card, a memory card, a universal serial bus (USB) device, etc. or may receive/transmit data from/to another system. In example embodiments, the CMOS image sensor 810 and the processor 840 may be integrally formed. In example embodiments, the CMOS image sensor 810 and the RAM 880 may be integrally formed. In example embodiments, the CMOS image sensor 810 may be a chip independent from the processor 840 and may be integrated with the processor 840.

The imaging system 800 may be applied to various apparatuses such as a digital camera, a camcorder, a mobile phone, a game device, a security camera, a micro camera for medical purposes, and a medical robot.

The foregoing is illustrative of example embodiments and is not to be construed as limiting thereof. Although a few example embodiments have been described, those skilled in the art will readily appreciate that many modifications are possible in example embodiments without materially departing from the novel teachings. Accordingly, all such modifications are intended to be included within the scope of the disclosure as defined in the claims. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A method of manufacturing a complementary metal oxide semiconductor (CMOS) image sensor, the method comprising:
forming, in a semiconductor substrate, at least one device isolation layer defining an active area;
forming at least one gate dielectric layer on the active area;
forming at least one gate on the active area and the at least one device isolation layer, wherein a plurality of first conductive-type impurity ions are injected into the at least one gate; and
injecting a plurality of second conductive-type impurity ions into portions of the at least one gate arranged on the at least one device isolation layer and edges of the active area adjacent to the at least one device isolation layer.

2. The method of claim 1, wherein the forming of the at least one gate includes,
forming a material layer on the at least one device isolation layer and the at least one gate dielectric layer;
injecting the first conductive-type impurity ions into the material layer; and
forming at least one gate by patterning the material layer.

3. The method of claim 2, wherein the forming the material layer includes using polysilicon.

4. The method of claim 1, wherein the injecting of the plurality of second conductive-type impurity ions includes,
forming a first photo mask pattern exposing the portions of the at least one gate and the edges of the active area;
injecting the second conductive-type impurity ions into the exposed portions of the at least one gate; and
removing the first photo mask pattern.

5. The method of claim 1, wherein the injecting of the plurality of second conductive-type impurity ions includes adjusting a threshold voltage of the edges of the active area to be greater than a threshold voltage of a central portion of the active area.

6. The method of claim 1, wherein the injecting of the second conductive-type impurity ions includes generating, by a voltage applied to the at least one gate, a greater amount of a current through a central portion of the active area than through the edges of the active area.

7. The method of claim 1, wherein an injection amount of the first conductive-type impurity ions is less than an injection amount of the second conductive-type impurity ions.

8. The method of claim 1, wherein the forming of the at least one gate includes forming a gate of a source-follower transistor, and
the source-follower transistor is configured to amplify a potential change of a floating diffusion area.

9. A method of manufacturing a complementary metal oxide semiconductor (CMOS) image sensor, the method comprising:
forming, in a semiconductor substrate, at least one device isolation layer defining an active area;
injecting a first plurality of first conductive-type impurity ions into a central portion of the active area;
forming a gate dielectric layer on the active area;
forming a material layer on the at least one device isolation layer and the gate dielectric layer;
injecting a second plurality of the first conductive-type impurity ions into the material layer; and
forming a gate by patterning the material layer.

10. The method of claim 9, wherein the injecting the first plurality of first conductive-type impurity ions includes injecting N-type impurity ions.

11. The method of claim 9, wherein an injection amount of the first plurality of the first conductive-type impurity ions is less than an injection amount of the second plurality of the first conductive-type impurity ions.

12. The method of claim 9, wherein the forming of the gate includes forming the gate between a reset gate and a select gate, and
the reset gate and select gate are formed in a selected area of the active area and are separated from each other by a set distance.

13. The method of claim 9, wherein a voltage applied to the gate generates a greater amount of a current through the central portion of the active area than through edges of the active area adjacent to the device isolation layers.

14. The method of claim 9, further comprising: after the forming of the gate,
injecting a plurality of second conductive-type impurity ions into a portion of the gate on the at least one device isolation layer and edges of the active area adjacent to the at least one device isolation layer.

15. The method of claim 14, wherein the injecting of the plurality of second conductive-type impurity ions includes injecting P-type impurity ions.

16. A method of manufacturing a complementary metal oxide semiconductor (CMOS) image sensor, the method comprising:
providing a semiconductor substrate including at least one device isolation layer defining an active area of the semiconductor substrate;
forming a material layer on the active area and the at least one device isolation layer;
forming a gate structure including a first impurity region and a second impurity region by performing a double doping process, the double doping process including injecting a first plurality of conductive-type impurity ions and subsequently injecting a second plurality of conductive-type impurity ions into the material layer; and
patterning the gate structure to form a gate,
wherein a dopant concentration of the first impurity region is different than a dopant concentration of the second impurity region.

17. The method of claim 16, wherein the performing the double doping process includes injecting the first plurality of conductive-type impurity ions in a central portion of the active area.

18. The method of claim 17, wherein the injecting the first plurality of conductive-type impurity ions and the injecting the second plurality of conductive-type impurity ions include injecting N-type impurity ions, and
an amount of the first plurality of conductive-type impurity ions is less than an amount of the second plurality of conductive-type impurity ions.

19. The method of claim 16, wherein the performing the double doping process includes,
injecting the first plurality of conductive-type impurity ions in a central portion of the material layer; and
injecting the second plurality of the conductive-type impurity ions into edges of the material layer.

20. The method of claim 19, further comprising:
forming a photo mask pattern exposing the edges of the material layer simultaneously with the injecting the second plurality of the conductive-type impurity ions,
wherein the forming the photo mask pattern and the injecting the second plurality of conductive-type impurity ions include injecting P-type impurity ions.
